(19) United States
(12) Patent Application Publication
(10) Pub. No.: US 2013/0049180 A1
(43) Pub. Date: Feb. 28, 2013

(54) QFN DEVICE AND LEAD FRAME THEREFOR

(71) Applicants: Nan XU, Tianjin (CN); Xingshou PANG, Tianjin (CN); Bin TIAN, Tianjin (CN); Shufeng ZHAO, Tianjin (CN)

(72) Inventors: Nan XU, Tianjin (CN); Xingshou PANG, Tianjin (CN); Bin TIAN, Tianjin (CN); Shufeng ZHAO, Tianjin (CN)

(73) Assignee: FREESCALE SEMICONDUCTOR, INC, Austin, TX (US)

(21) Appl. No.: 13/549,517

(22) Filed: Jul. 15, 2012

(30) Foreign Application Priority Data
Aug. 30, 2011 (CN) 201110326978.3

(51) Int. Cl. H01L 23/495; H01L 21/60

(52) U.S. Cl. 257/670; 438/123; 257/E23.032; 257/E21.506

(57) ABSTRACT

A lead frame for a quad flat no-lead (QFN) type semiconductor device package includes a die pad, a plurality of leads that surround the die pad. The outer edge of leads includes a channel that extends from a lower surface to an upper surface of the leads. A semiconductor die is attached to the die pad. An inner edge of each lead is electrically connected to a corresponding bonding pad on the semiconductor die. The assembly is covered with an encapsulation material except that the outer edge of each lead and the corresponding channel are exposed. The channel allows solder to flow up the outer edge of a lead when the QFN device is soldered to a substrate, which improves the ability to perform visual inspection of the solder-lead connection.

### BACKGROUND OF THE INVENTION

The present invention relates to semiconductor packaging, and more particularly, to a lead frame for assembling quad flat no-lead (QFN) type semiconductor devices.

QFN and PQFN (Power QFN) semiconductor packages are widely used owing to their small size, moderate thermal dissipation and good electrical performance. Such packages are usually assembled using a lead frame with a die pad and a plurality of leads surrounding the die pad. A semiconductor die is attached to the die pad, electrically connected to the leads, and then the lead frame, die and electrical connections are covered with an encapsulation material. FIG. 1A shows a top view of a conventional lead frame 100 used in a QFN package. The lead frame 100 includes a die pad 102 for attaching a semiconductor die (not shown in FIG. 1A) and a plurality of leads 104 that surround the die pad 102. Tie bars 105 support the die pad 102.

FIG. 1B shows a cross-sectional side view of a conventional QFN device 106. The conventional QFN device 106 includes the lead frame 100 having the leads 104 and the die pad 102. A semiconductor die 108 is attached to the die pad 102. The leads 104 are electrically connected to corresponding bonding pads 110 on the semiconductor die 108 with bond wires 112, with a wire-bonding process. The assembly including the lead frame 100, the leads 104, the semiconductor die 108, and the bond wires 112 is covered with an encapsulation material 114 to form the conventional QFN device 106. As shown in FIG. 1B, the outer edge of the leads 104 are exposed and not covered with the encapsulation material 114. The exposed portions of the leads 104 may be soldered to a substrate (not shown), such as a printed circuit board (PCB).

The quality of the solder joints is checked during inspection. Many techniques including visual inspection, optical inspection, x-ray microscopy and endoscopy are used to check the quality of solder joints. Visual inspection of solder fillets (solder filled in the solder joints) is among the most widely used techniques for checking the quality of solder joints because of its ease and cost-effectiveness. However, visual inspection is not always effective. With the ever shrinking size of semiconductor devices, many QFN devices may be closely placed on a substrate such that when a QFN device is mounted on a substrate, the solder fillets are not visible and the visual inspection can only be performed from the top and side surfaces. Hence, visual inspection of the solder fillets becomes difficult and ineffective.

Therefore, there is a need to enhance the effectiveness of visual inspection of solder joints for QFN type semiconductor device packages.

### BRIEF DESCRIPTION OF THE DRAWINGS

The following detailed description of the preferred embodiments of the present invention will be better understood when read in conjunction with the appended drawings. The present invention is illustrated by way of example, and not limited by the accompanying figures, in which like references indicate similar elements. It is to be understood that the drawings are not to scale and have been simplified for ease of understanding the invention.

FIG. 1A is a top view of a conventional lead frame used in QFN type semiconductor device packages;

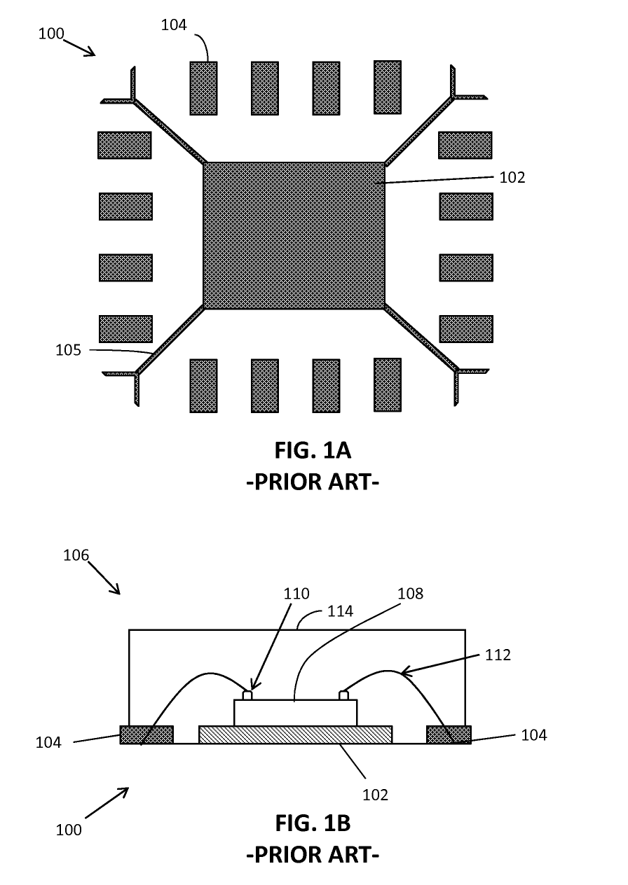

FIG. 1B is a cross-sectional side view of a conventional QFN semiconductor device package;

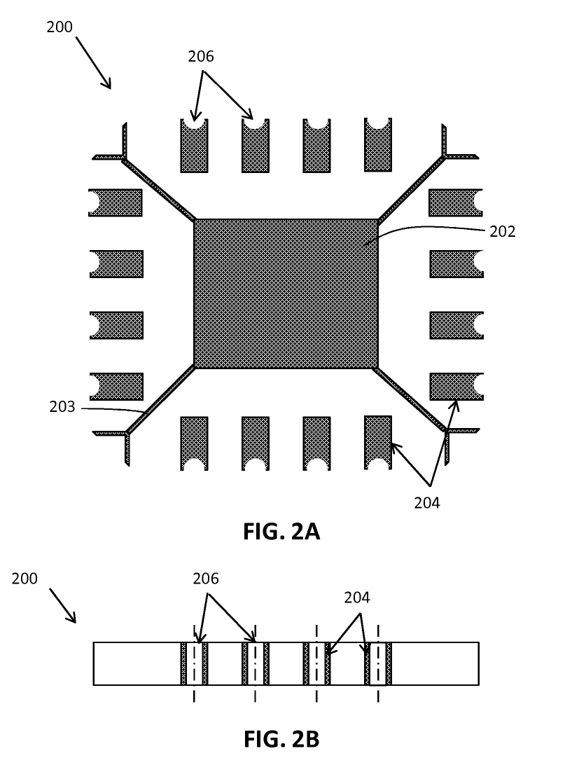

FIGS. 2A and 2B are top and front views, respectively, of a lead frame, in accordance with an embodiment of the present invention;

FIG. 3 is a top view of the lead frame shown in FIG. 2A with a semiconductor die attached thereto in accordance with an embodiment of the present invention;

FIGS. 4A and 4B are top and perspective views, respectively, of a QFN type semiconductor device package in accordance with an embodiment of the present invention; and

FIG. 5 is a flowchart illustrating a method for assembling a QFN type semiconductor device package in accordance with an embodiment of the present invention.

### DETAILED DESCRIPTION OF THE PRESENT INVENTION

The detailed description of the appended drawings is intended as a description of the currently preferred embodiments of the present invention, and is not intended to represent the only form in which the present invention may be practiced. It is to be understood that the same or equivalent functions may be accomplished by different embodiments that are intended to be encompassed within the spirit and scope of the present invention.

In an embodiment of the present invention, a lead frame for a semiconductor device package is provided. The lead frame includes a die pad and a plurality of leads that surround the die pad. A channel is formed at an outer edge of each lead and extends from a lower surface to an upper surface of the lead. The channel facilitates visual inspection of the solder joints of the semiconductor device package after it has been attached to a substrate such as a printed circuit board (PCB).

In another embodiment of the present invention, a semiconductor device package is provided. The semiconductor device package includes a die pad and a semiconductor die attached to the die pad. A plurality of leads surrounds the die pad. The inner edge of each lead is electrically connected to a corresponding bonding pad on the semiconductor die. A channel is formed at an outer edge of each lead and extends from a lower surface to an upper surface of the lead. An encapsulation material covers the die pad, the semiconductor die and the plurality of leads, except that the outer edge of each lead and the corresponding channel are exposed. The channels allow solder to flow up the outer edges of the leads when the semiconductor device package is soldered to a substrate, thereby enhancing visual inspection of the solder-lead connection.

In yet another embodiment of the present invention, a method for assembling a semiconductor device is provided. A lead frame having a die pad and a plurality of leads surrounding the die pad is provided. A channel is formed at an outer edge of each lead such that the channel extends from a lower surface to an upper surface of each lead. A semiconductor die is attached to the die pad. The inner edge of each lead is electrically connected to a corresponding bonding pad on the semiconductor die. The semiconductor die, the die pad and the leads are covered with an encapsulation material except that the outer edge of each lead and the corresponding channel are exposed. The channels allow solder to flow up the outer edge of the lead when the semiconductor device is soldered to a substrate, thereby enhancing visual inspection of the solder-lead connection.

Various embodiments of the present invention provide a packaged semiconductor device. Although the invention is described below with particular reference to a quad flat no-lead (QFN) type semiconductor device package and a process for assembling a QFN semiconductor device, it will be understood by those of skill in the art that the inventive concept described herein may apply to other types of semiconductor device packages. The channels formed at the outer edges of the leads allow solder to flow up the outer edges of the leads when the packaged semiconductor device is soldered to a substrate. The solder fillets can be easily viewed from the top and side surfaces, which makes visual inspection of solder joints (solder-lead connection) more effective, even on substrates that have closely arranged devices.

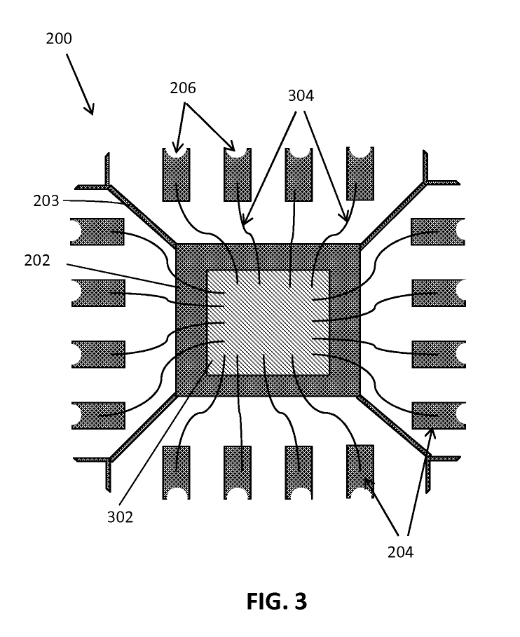

Referring now to FIGS. 2A and 2B, top and front views respectively of a lead frame 200 in accordance with an embodiment of the present invention are shown. The lead frame 200 includes a die pad 202 for attaching a semiconductor die (not shown in FIG. 2A), tie bars 203 attached to the die pad 202, and a plurality of leads 204 (collectively referred to as leads 204) that surround the die pad 202. Each tie bar 203 extends from an edge of the lead frame 200 to the corresponding edge of the die pad 202. The thickness of each lead 204 is about 0.127 mm to 0.508 mm. The outer edge of each lead 204 includes a channel 206 that extends from a lower surface (not shown in FIG. 2A) to an upper surface (visible surface of FIG. 2A) of the lead 204. In an embodiment of the present invention, the channel 206 may be formed by cutting a hole through the outer edge of each lead 204. In various embodiments of the present invention, the channels 206 may be formed by using any of the etching, drilling, punching and cutting operations. The channel 206 extends about 0.05 mm to 0.1 mm inwards from an outer edge of each lead 204.

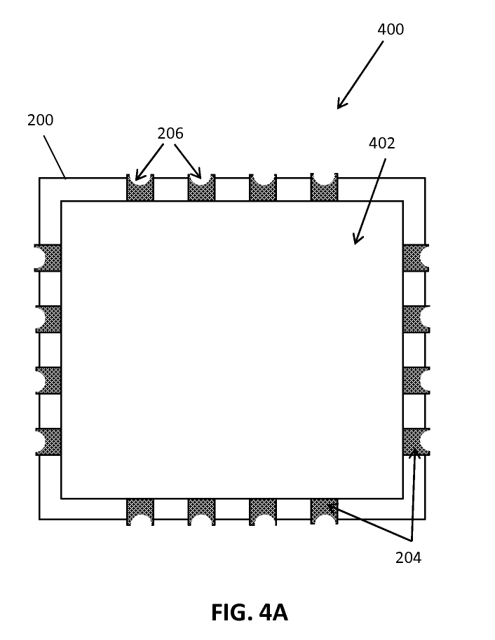

The lead frame 200, as shown in FIGS. 2A and 2B, is used to assemble a quad flat non-leaded (QFN) semiconductor device. Referring now to FIG. 3, a top view of the lead frame 200 with a semiconductor die 302 in accordance with an embodiment of the present invention is shown. The semiconductor die 302 is attached to the die pad 202. In various embodiments of the present invention, the semiconductor die 302 is attached to the die pad 202 using a thermally conductive adhesive. The inner edge of each lead 204 is electrically connected to a corresponding bonding pad (not shown) of the semiconductor die 302 by wire-bonding process. Bond wires 304 connect the leads 204 to the corresponding bonding pads of the semiconductor die 302. Though wire-bonding process is shown to be used, it will be understood that any other suitable process such as flip-chip (also referred to as Controlled Collapse Chip Connection, or C4) or tape automated bonding process may be used to form the electrical connections between the leads 204 and the corresponding bonding pads.

The lead frame 200, the semiconductor die 302, the leads 204, and the bond wires 304 as shown in FIG. 3, are covered by an encapsulation material to form a quad flat no-lead (QFN) semiconductor device package.

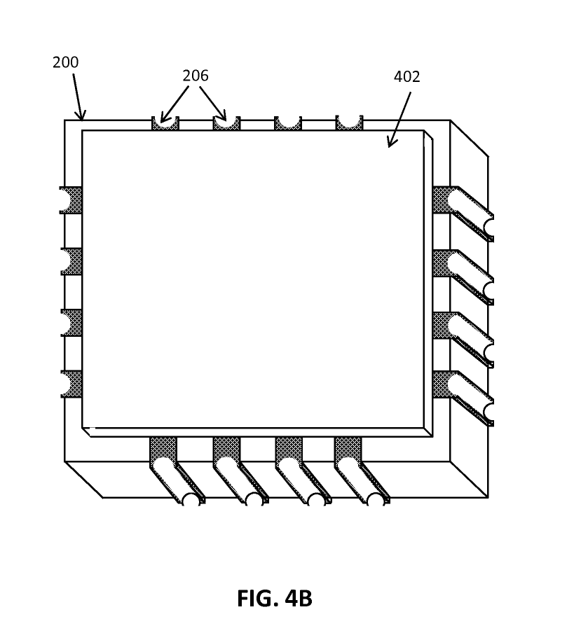

Referring now to FIGS. 4A and 4B, top and perspective views, respectively, of a QFN semiconductor device package 400, in accordance with an embodiment of the present invention are shown. The lead frame 200, the semiconductor die 302, the bond wires 304 and the leads 204 are covered by an encapsulation material 402 except that the outer edge of the leads 204 and the channels 206 are exposed. The QFN semiconductor device package 400 is about 3×3 mm and 9×9 mm in size. In various embodiments of the present invention, suitable compounds such as an epoxy resin, phenolic hardeners, silicas and mold release agents may be used as the encapsulation material 402. Any suitable existing molding apparatus may be used to dispense the molding compound above the lead frame 200 to form the encapsulation.

The connections on the QFN semiconductor device package 400 are externally made using fillet solder joints. The exposed part of the leads 204 is used to solder the QFN semiconductor device package 400 to a substrate or a printed circuit board (PCB). The channels 206 allow the solder to flow up through the outer edge of the leads 204 to the upper surface during the solder reflow process. As a result, the solder fillets can be easily viewed from the top and side surfaces of thee QFN semiconductor device package 400 and visual inspection of the solder joints becomes easy.

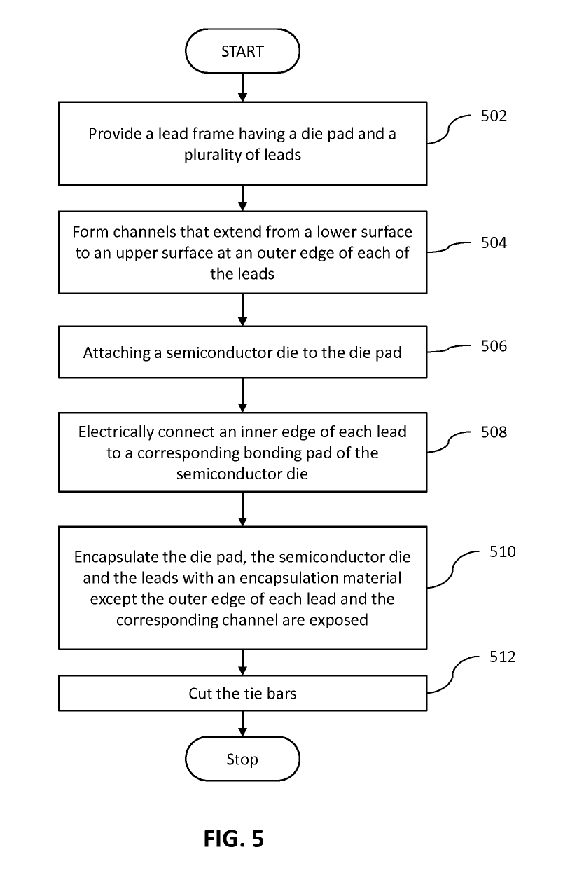

Referring now to FIG. 5, a flowchart illustrating a method for assembling the QFN semiconductor device in accordance with an embodiment of the present invention is shown. Various steps of the flowchart have been explained in conjunction with FIGS. 2A, 2B, 3, 4A and 4B. At step 502, the lead frame 200 along with the die pad 202, tie bars 203, and leads 204 surrounding the die pad 202 is provided. At step 504, channels 206 are formed at outer edges of corresponding leads 204 such that each channel 206 extends from the lower surface to the upper surface of corresponding lead 204. The channels 206 may be formed using any of the existing techniques such as etching, drilling, punching and cutting. At step 506, the semiconductor die 302 is attached to the die pad 202. At step 508, the inner edge of each lead 204 is electrically connected to a corresponding bonding pad on the semiconductor die 302. In an embodiment of the present invention, the electrical connection may be made using wire-bonding process. At step 510, the assembly of the semiconductor die 302, the die pad 202 and the leads 204 is covered by an encapsulation material 402. The encapsulation is performed in such a manner that the outer edge of each lead 204 and the corresponding channel 206 are exposed for external electrical connections. The channels 206 in the leads 204 allow the solder to flow up the outer edge of the leads 204 when the QFN semiconductor device 400 is soldered to a substrate. As a result, the solder joints can be easily inspected from the top as well as the side views. The visibility of the solder joints enhances the visual inspection of the solder-lead connection.

The description above is provided in reference to QFN semiconductor devices. It should be apparent to a person skilled in the art that the present invention is applicable for Power-QFN (PQFN) semiconductor devices as well.

Finally, the terminology used herein is for the purpose of describing particular embodiments only and is not intended to be limiting of example embodiments of the invention. As used herein, the singular forms “a,” “an,” and “the,” are intended to include the plural forms as well, unless the context clearly indicates otherwise. Also, terms “device” and “package” have been used interchangeably. It will be further understood that the terms “comprises,” “comprising,” “includes,” and/or “including,” when used herein, specify the presence of stated features, integers, steps, operations, elements, and/or components, but do not preclude the presence or addition of one or more other features, integers, steps, operations, elements, components, and/or groups thereof. It should be understood that, although the terms first, second, etc. and horizontal and vertical are used to describe various elements, these elements should not be limited by these terms. These terms are only used to distinguish one element from another. For example, a first element could be termed a second element, and, similarly, a second element could be termed a first element, without departing from the scope of example embodiments of the present invention. As used herein, the term “and/or,” includes any and all combinations of one or more of the associated listed items.

While various embodiments of the present invention have been illustrated and described, it will be clear that the present invention is not limited to these embodiments only. Numerous modifications, changes, variations, substitutions, and equivalents will be apparent to those skilled in the art, without departing from the spirit and scope of the present invention, as described in the claims.

What claimed is:

1. A lead frame for a semiconductor device package, the lead frame comprising:
a die pad;
a plurality of tie bars that support the die pad; and
a plurality of leads that surround the die pad, wherein an outer edge of each lead has a channel formed therein that extends from a lower surface of the lead to an upper surface of the lead.

2. The lead frame of claim 1, wherein the channel extends from the outer edge of the lead inward by about 0.05 mm to 0.1 mm.

3. The lead frame of claim 1, wherein each lead has a thickness of about 0.127 mm to 0.504 mm.

4. The lead frame of claim 1, wherein the channels are formed in the leads using at least one of an etching, drilling, punching and a cutting operation.

5. The lead frame of claim 1, wherein the channels comprise through holes.

6. A packaged semiconductor device, comprising:
a die pad;
a semiconductor die attached to the die pad;
a plurality of leads that surround the die pad, wherein an inner edge of each lead is electrically connected to a corresponding bonding pad on the semiconductor die, wherein an outer edge of each lead has a channel formed therein that extends from a lower surface of the lead to an upper surface of the lead; and
an encapsulation material that covers the die pad, the semiconductor die and the plurality of leads, wherein the outer edge of each lead and the corresponding channel are exposed to allow solder to flow up the outer edge of each lead when the packaged device is soldered to a substrate, thereby permitting visual inspection of the solder-lead connection.

7. The packaged semiconductor device of claim 6, wherein the channel extends from an outer edge of the lead inward by about 0.05 mm to 0.1 mm.

8. The packaged semiconductor device of claim 6, wherein each lead has a thickness of about 0.127 mm to 0.508 mm.

9. The packaged semiconductor device of claim 6, wherein the thickness of the package is about 3×3 mm and 9×9 mm.

10. The packaged semiconductor device of claim 6, wherein the inner edge of each lead is electrically connected to the corresponding bonding pad on the semiconductor die with a wire.

11. The packaged semiconductor device of claim 6, wherein the package comprises a Quad Flat No Lead (QFN) type package.

12. The packaged semiconductor device package of claim 11, wherein the semiconductor die comprises a power die and the packaged device comprises a power QFN (PQFN) package.

13. A method of assembling a semiconductor device, comprising;
providing a lead frame having are die pad, and a plurality of leads that surround the die pad;
forming a channel at an outer edge of each lead, wherein the channel extends from a lower surface to an upper surface of the lead;
attaching a semiconductor die to the die pad;
electrically connecting an inner edge of each lead to a corresponding bonding pad on the semiconductor die; and
encapsulating the die pad, the semiconductor die and the plurality of leads by an encapsulation material, wherein the outer edge of each lead and the corresponding channel are exposed to allow solder to flow up the outer edge of the lead when the assembled semiconductor device is soldered to a substrate, thereby enhancing visual inspection of the solder-lead connection.

14. The method of claim 13, wherein the channel is formed using at least one of an etching, drilling, punching and a cutting operation.

15. The method of claim 13, wherein the electrically connecting step comprises a wire-bonding process.
